(19) United States
(12) Patent Application Publication
(10) Pub. No.: US 2022/0381818 A1
(43) Pub. Date: Dec. 1, 2022

(54) WAFER INSPECTION APPARATUS AND WAFER INSPECTION METHOD

(71) Applicant: SEMES CO., LTD., Cheonan-si (KR)

(72) Inventor: Hyuk Ju LEE, Asan-si (KR)

(73) Assignee: SEMES CO., LTD., Cheonan-si (KR)

(21) Appl. No.: 17/725,157

(22) Filed: Apr. 20, 2022

(30) Foreign Application Priority Data
May 26, 2021 (KR) 10-2021-0067379

(51) Int. Cl. G01R 31/28; G01R 1/067

(52) U.S. Cl. CPC G01R 31/2831; G01R 31/2881; G01R 31/2874; G01R 1/06705

(57) ABSTRACT

Proposed is a wafer inspection apparatus and a wafer inspection method, which can increase inspection accuracy while reducing the amount of dry air used. The wafer inspection apparatus includes a chamber providing a space for an electrical test of a wafer, a support unit positioned inside the chamber to support the wafer, a temperature control unit for controlling a test temperature of the wafer, a dry air supply unit for supplying dry air to the chamber, and a flow control unit for controlling the dry air supply unit to adjust flow rate of the dry air based on the test temperature. The wafer inspection apparatus and the wafer inspection method of the present disclosure may increase the accuracy of the wafer inspection while preventing the drying air from being wasted by variably adjusting the flow rate of dry air supplied based on the test temperature of the wafer.

### CROSS REFERENCE TO RELATED APPLICATION

The present application claims priority to Korean Patent Application No. 10-2021-0067379, filed May 26, 2021, the entire contents of which is incorporated herein for all purposes by this reference.

### BACKGROUND OF THE INVENTION

### Field of the Invention

The present disclosure relates to a wafer inspection apparatus and a wafer inspection method and, more particularly, to a wafer inspection apparatus and a wafer inspection method for variably controlling the flow rate of dry air to prevent condensation in a chamber.

### Description of the Related Art

A semiconductor manufacturing process is a process to fabricate semiconductor devices on a substrate (e.g., a wafer), and includes, for example, exposure, deposition, etching, ion implantation, and cleaning. Meanwhile, an electrical die sorting (EDS) process for conducting an electrical test of each device formed on the wafer is performed.

In the EDS process, a probe card with a plurality of pins contacts the wafer, applies electrical signals to the wafer, and based on the response, each semiconductor device of the wafer is inspected. This electrical test is performed in various temperature environments, and the test may be performed in a low temperature environment (e.g., −20° C.) and a high temperature environment (e.g., 60° C.)

When testing in a low temperature environment, if moisture exists around the wafer, condensation occurs, so it is important to create a dry environment with almost no moisture when testing in a low temperature environment, and thus a sufficient amount of dry air is supplied to an inspection chamber when inspecting wafers. However, in the case of a high temperature environment, when a large amount of dry air is supplied as in a low temperature environment even though condensation does not occur, there arises a problem that the amount of dry air used becomes excessively large.

### SUMMARY OF THE INVENTION

Accordingly, the present disclosure has been made keeping in mind the above problems occurring in the related art, and the present disclosure is intended to provide a wafer inspection apparatus and a wafer inspection method, which can increase inspection accuracy while reducing the amount of dry air used.

The objectives of the present disclosure are not limited to those mentioned above, and other objectives not mentioned will be clearly understood by those skilled in the art from the following description.

In order to achieve the above objective, according to an embodiment of the present disclosure, there is provided a wafer inspection apparatus including: a chamber providing a space for an electrical test of a wafer; a support unit positioned inside the chamber to support the wafer; a temperature control unit for controlling a test temperature of the wafer; a dry air supply unit for supplying dry air to the chamber; and a flow control unit for controlling the dry air supply unit to adjust flow rate of the dry air based on the test temperature.

According to an embodiment of present disclosure, the dry air supply unit may include: an inlet through which the dry air is introduced; a first supply line connected to the inlet and configured for the dry air to flow at a first flow rate; a second supply line connected to the inlet and configured for the dry air to flow at a second flow rate lower than the first flow rate; a switch valve for directing the dry air introduced through the inlet to one of the first supply line or the second supply line; an outlet connected to each of the first supply line and the second supply line for discharging the dry air to the chamber; and a flow meter provided at the outlet to measure the flow rate of the dry air discharged into the chamber.

According to an embodiment of present disclosure, the first supply line may include: a first conduit through which the dry air flows; a first speed controller for controlling the dry air to flow at the first flow rate in the first conduit; and a first check valve for guiding the dry air to flow in a direction of the outlet and blocking the dry air from flowing in an opposite direction of the outlet.

According to an embodiment of present disclosure, the second supply line may include: a second conduit through which the dry air can flow; a second speed controller for controlling the dry air to flow at the second flow rate in the second conduit; and a second check valve for guiding the dry air to flow in a direction of the outlet and blocking the dry air from flowing in an opposite direction of the outlet.

According to an embodiment of present disclosure, the flow control unit may control the switch valve so that the dry air flows to the first supply line when the test temperature corresponds to a first temperature, and control the switch valve so that the dry air flows to the second supply line when the test temperature corresponds to a second temperature higher than the first temperature.

According to an embodiment of present disclosure, the dry air supply unit may include: an inlet through which the dry air is introduced; a conduit connected to the inlet and through which the dry air flows; an electropneumatic regulator provided in the conduit to variably control the flow rate at which the dry air flows; an outlet connected to the conduit for discharging the dry air to the chamber; and a flow meter provided at the outlet to measure the flow rate of the dry air discharged into the chamber.

According to an embodiment of present disclosure, the flow control unit may control the electropneumatic regulator to discharge the dry air at a first pressure corresponding to a first flow rate so that the dry air flows at the first flow rate when the test temperature corresponds to a first temperature, and control the electropneumatic regulator to discharge the dry air at a second pressure corresponding to a second flow rate so that the dry air flows at the second flow rate when the test temperature corresponds to a second temperature higher than the first temperature.

According to an embodiment of present disclosure, the wafer inspection apparatus further includes a hygrometer configured to measure humidity inside the chamber, and the flow control unit may adjust a supply flow rate of the dry air based on humidity data measured by the hygrometer.

According to an embodiment of present disclosure, a wafer inspection method includes: placing a wafer in a chamber; setting a test temperature of the wafer; supplying dry air of a set flow rate to the chamber based on the set test temperature; and performing an electrical test on the wafer at the set test temperature.

According to an embodiment of present disclosure, the supplying dry air to the chamber may include: supplying the dry air to the chamber at a first flow rate when the test temperature corresponds to a first temperature; and supplying the dry air to the chamber at a second flow rate smaller than the first flow rate when the test temperature corresponds to a second temperature higher than the first temperature.

According to an embodiment of present disclosure, a probe station includes: a loader unit that loads a wafer and unloads an inspected wafer; an inspection unit for contacting the wafer to a probe card for inspection of the wafer; and an interface unit providing a space in which the probe card and a test head are electrically connected. The inspection unit a chamber providing a space for an electrical test of the wafer; a temperature control unit for controlling a test temperature of the chamber; a dry air supply unit for supplying dry air to the chamber; and a flow control unit for adjusting the supply flow rate of the dry air based on the test temperature. The the flow control unit supplies the dry air at a first flow rate when the test temperature is a first temperature, and supplies the dry air at a second flow rate lower than the first flow rate when the test temperature is a second temperature higher than the first temperature.

According to an embodiment of present disclosure, the dry air supply unit may include: an inlet through which the dry air is introduced; a first supply line connected to the inlet and configured for the dry air to flow at the first flow rate; a second supply line connected to the inlet and configured for the dry air to flow at the second flow rate lower than the first flow rate; a switch valve for directing the dry air introduced through the inlet to one of the first supply line or the second supply line; an outlet connected to each of the first supply line and the second supply line for discharging the dry air to the chamber; and a flow meter provided at the outlet to measure the flow rate of the dry air discharged into the chamber.

According to an embodiment of present disclosure, the first supply line may include: a first conduit through which the dry air flows; a first speed controller for controlling the dry air to flow at the first flow rate in the first conduit; and a first check valve for guiding the dry air to flow in a direction of the outlet and blocking the dry air from flowing in an opposite direction of the outlet.

According to an embodiment of present disclosure, the second supply line may include: a second conduit through which the dry air flows; a second speed controller for controlling the dry air to flow at the second flow rate in the second conduit; and a second check valve for guiding the dry air to flow in a direction of the outlet and blocking the dry air from flowing in an opposite direction of the outlet.

According to an embodiment of present disclosure, the flow control unit may control the switch valve so that the dry air flows to the first supply line when the test temperature corresponds to the first temperature, and control the switch valve so that the dry air flows to the second supply line when the test temperature corresponds to the second temperature higher than the first temperature.

According to an embodiment of present disclosure, the dry air supply unit may include: an inlet through which the dry air is introduced; a conduit connected to the inlet and through which the dry air can flow; an electropneumatic regulator provided in the conduit to variably control the flow rate at which the dry air flows; an outlet connected to the conduit for discharging the dry air to the chamber; and a flow meter provided at the outlet to measure the flow rate of the dry air discharged into the chamber.

According to an embodiment of present disclosure, the flow control unit may control the electropneumatic regulator to discharge the dry air at a first pressure corresponding to the first flow rate so that the dry air flows at the first flow rate when the test temperature corresponds to the first temperature, and control the electropneumatic regulator to discharge the dry air at a second pressure corresponding to the second flow rate so that the dry air flows at the second flow rate when the test temperature corresponds to the second temperature higher than the first temperature.

According to an embodiment of present disclosure, the dry air supply unit may be configured to supply the dry air to the interface unit.

According to an embodiment of present disclosure, the flow control unit may adjust the supply flow rate of the dry air supplied to the interface unit based on the test temperature.

According to an embodiment of present disclosure, the inspection unit further includes a hygrometer configured to measure humidity inside the chamber, and the flow control unit may adjust the supply flow rate of the dry air based on humidity data measured by the hygrometer.

According to the wafer inspection apparatus and the wafer inspection method according to the embodiments of the present disclosure, it is possible to increase the accuracy of the wafer inspection while preventing the drying air from being wasted by variably adjusting the flow rate of dry air supplied based on the test temperature of the wafer.

The effects of the present disclosure are not limited to those mentioned above, and other effects not mentioned will be clearly understood by those skilled in the art from the following description.

### BRIEF DESCRIPTION OF THE DRAWINGS

The above and other objectives, features, and other advantages of the present disclosure will be more clearly understood from the following detailed description when taken in conjunction with the accompanying drawings, in which:

FIGS. 1 and 2 are perspective views of a probe station for performing an electrical test of a wafer;

FIG. 3 shows a schematic configuration of a probe station according to an embodiment of the present disclosure;

FIG. 4 shows a process in which tips of the probe card and pads of the wafer are in contact;

FIG. 5 shows a wafer inspection apparatus to which a dry air supply unit is applied according to the embodiment of the present disclosure;

FIGS. 6 and 7 illustrate a process of supplying dry air from the dry air supply unit according to the embodiment of the present disclosure;

FIG. 8 shows a wafer inspection apparatus to which a dry air supply unit is applied according to an embodiment of the present disclosure;

FIGS. 9 and 10 illustrate a process of supplying dry air from the dry air supply unit according to an embodiment of the present disclosure;

FIG. 11 shows a wafer inspection apparatus to which a dry air supply unit is applied according to an embodiment of the present disclosure;

FIG. 12 shows a case in which dry air is supplied to an interface unit using the dry air supply unit according to an embodiment of the present disclosure;

FIG. 13 is a flowchart illustrating a wafer inspection method according to the present disclosure;

FIG. 14 is a flowchart illustrating a process of supplying dry air according to an embodiment of the present disclosure; and

FIG. 15 is a flowchart illustrating a process of supplying dry air according to an embodiment of the present disclosure.

### DETAILED DESCRIPTION OF THE INVENTION

Hereinafter, with reference to the accompanying drawings, embodiments of the present disclosure will be described in detail so that those of ordinary skill in the art can easily carry out the present disclosure. The present disclosure may be embodied in many different forms and is not limited to the embodiments described herein.

In order to clearly explain the present disclosure, parts irrelevant to the description are omitted, and the same reference numerals are given to the same or similar elements throughout the specification.

In addition, in various embodiments, components having the same configuration will be described only in the representative embodiment using the same reference numerals, and only configurations different from the representative embodiment will be described in other embodiments.

Throughout the specification, when a part is said to be “connected (or coupled)” with another part, this includes not only the case of “directly connected (or coupled)” but also the case of “indirectly connected (or coupled)” with another member therebetween. In addition, when a part “includes” a certain component, it means that other components may be further included, rather than excluding other components, unless otherwise stated.

Unless defined otherwise, all terms used herein, including technical or scientific terms, have the same meaning as commonly understood by those of ordinary skill in the art to which the present disclosure pertains. Terms such as those defined in a commonly used dictionary should be interpreted as having a meaning consistent with the meaning in the context of the related art, unless explicitly defined in this application, it should not be construed in an ideal or overly formal sense.

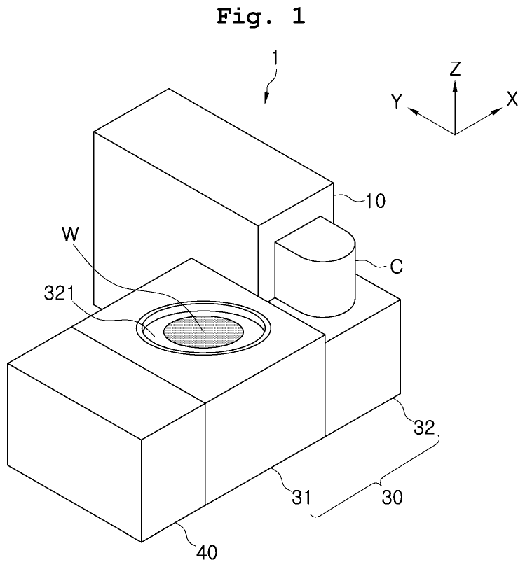

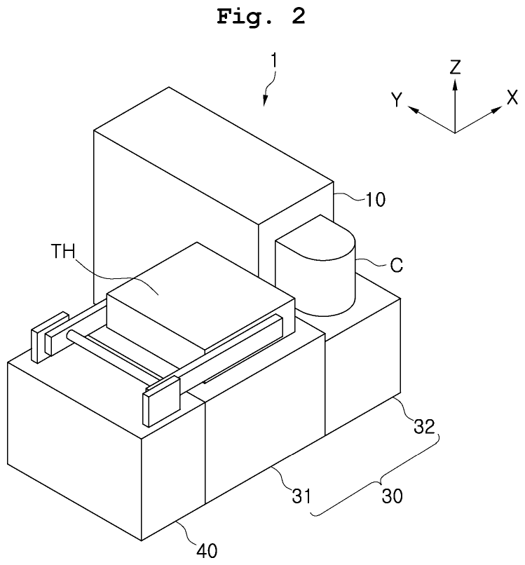

FIGS. 1 and 2 are perspective views illustrating the outside of a probe station for performing an electrical test of a wafer. FIG. 1 shows the probe station 1 in a state in which a test head TH is not engaged, and FIG. 2 shows the probe station 1 in a state in which the test head TH is engaged.

The probe station 1 is a device that provides an environment for electrical testing of the wafer W on which semiconductor devices are formed, and is configured to contact the wafer W with the probe card PC after the temperature for inspection is set. More specifically, the wafer W put into the probe station 1 is aligned with the probe card PC while seated on the chuck 321 inside the chamber 310, and then rises and comes into contact with the tips of the probe card PC. Here, various temperature chamber 310 environments may be created including a low temperature environment (e.g., −20° C.) and a high temperature environment (e.g., 60° C.), and the wafer W may be inspected at various temperatures. When the wafer W comes into contact with the probe card PC, electrical signals are applied by the test head TH connected to the probe card PC, and then it is possible to inspect the state of each semiconductor device by analyzing the response of each semiconductor device on the wafer W to the input electrical signals.

Referring to FIGS. 1 and 2, a carrier C on which a plurality of wafers W are loaded is put into a loader unit 10, and the loader unit 10 removes the wafers W from the carrier C and then transfers the wafers W to the chuck 321 of the support unit 320 provided in the chamber 310. Although not specifically shown, the loader unit 10 may include an opener that opens the door of the carrier C and a wafer transfer robot that transfers the wafers W from the carrier C.

The wafers W put into the loader unit 10 are transferred to the inspection unit 30 by the wafer transfer robot, and the wafers W may be inspected. The inspection unit 30 may include a stage unit 31 for inspection and a controller 32 for controlling the operation of the probe station. The stage unit 31 provides an environment for inspection of the wafer W, and the controller 32 includes modules for motion control. Also, a hinge drive unit 40 for driving the hinge of the test head TH may be positioned on a side surface of the stage unit 31.

Although not shown, a tester is provided outside the probe station 1, and the tester performs a wafer test by applying electrical signals to the semiconductor devices on the wafer W through the test head TH and analyzing the response from each semiconductor device. The test head TH is mounted on the hinge drive unit 40 and located at the upper end of the stage unit 31, and the test is performed when the probe card PC connected to the test head TH through the interface unit 20 comes into contact with the wafer W.

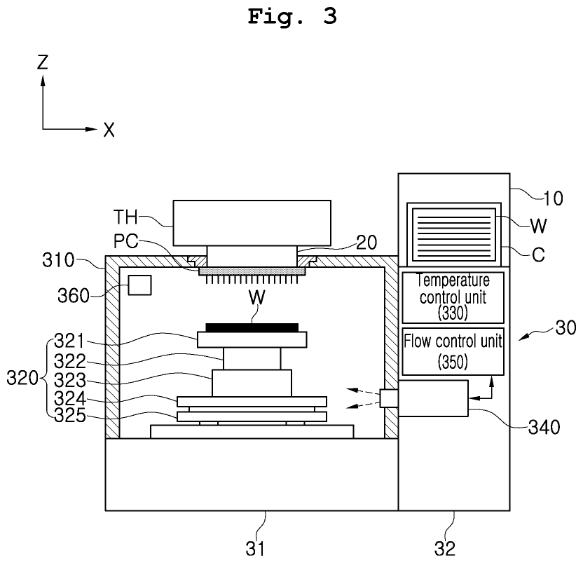

FIG. 3 shows a schematic configuration of a probe station according to an embodiment of the present disclosure. The probe station 1 according to the present disclosure includes: a loader unit 10 that loads a wafer W and unloads an inspected wafer W; an inspection unit 30 for contacting the wafer to a probe card PC for inspection of the wafer W; and an interface unit 20 that electrically connects the probe card PC and a test head TH.

The inspection unit 30 includes: a chamber 310 providing a space for an electrical test; a support unit 320 positioned inside the chamber 310 to support the wafer W; a temperature control unit 330 for controlling a test temperature of the wafer W; a dry air supply unit 340 for supplying dry air to the chamber 310; and a flow control unit 350 for controlling the dry air supply unit 340 to adjust flow rate of the dry air based on the test temperature.

In this document, dry air refers to the air without water vapor, and refers to the air having a humidity substantially below a reference value (e.g., 0.1%).

Here, the support unit 320 may include: a chuck 321 on which the wafer W is seated; a vertical drive shaft 322 and a vertical drive unit 323 for raising or lowering the chuck 321; a first horizontal drive unit 324 for moving the chuck 321 in a first horizontal direction (e.g., Y direction); and a second horizontal drive unit 325 for moving the chuck 321 in a second horizontal direction (e.g., X direction).

When the wafer W is transferred into the chamber 310 and seated on the chuck 321, the chuck 321 is moved by the first horizontal drive unit 324 and the second horizontal drive unit 325 so that the probe card PC and the wafer W are aligned. Here, a vision inspection unit (not shown) for checking the relative positions of the probe card PC and the wafer W may be provided in the upper and lower portions of the chamber 310, respectively.

In addition, a hygrometer 360 for measuring the humidity inside the chamber 310 may be provided inside the chamber 310. The flow control unit 350 may adjust the supply flow rate of dry air based on the humidity data measured by the hygrometer 360. For example, when the humidity inside the chamber 310 is higher than the reference value, the flow control unit 350 may control the dry air supply unit 340 to supply more dry air into the chamber 310.

Also, as previously described, the temperature inside the chamber 310 is adjusted to a low or high temperature by the temperature control unit 330 for testing in various temperature environments. The temperature control unit 330 may heat or cool the wafer W by adjusting the temperature of the chuck 321. A heating device for heating may be provided inside the chuck 321, and a cooling device for cooling may be located outside the probe station 1. The temperature of the chuck 321 may be controlled by flowing of the low-temperature fluid supplied through the cooling device through an internal flow path of the chuck 321.

In the case of normal air, since it contains a certain amount of moisture, condensation may occur on the wafer W or the probe card PC in a low temperature environment. Accordingly, the dry air supply unit 340 continuously supplies the dry air into the chamber 310 to prevent condensation.

Meanwhile, if dry air is continuously supplied even in a high temperature environment, the consumption of dry air becomes excessively high. Therefore, a method of stopping the supply of dry air when switching from a low temperature environment to a high temperature environment may be considered. However, if dry air is not supplied at all in a high temperature environment, when switching from a high temperature environment to a low temperature environment, it takes too much time to remove moisture inside the chamber 310, and moisture may exist inside due to moisture in a high temperature environment, which may cause condensation during low temperature testing. Therefore, it is advantageous in terms of facility efficiency of the probe station 1 to provide a predetermined amount of dry air even in a high temperature environment to create a constant drying environment.

In particular, in the wafer W, the pads that the tips 410 of the probe card PC contact are made of aluminum (Al), and an oxide film (Al2O3) is formed on the upper surface of the aluminum (Al) over a period of time. Thus, when the tips 410 of the probe card PC simply contact the pads, a test failure may occur due to the oxide film (Al2O3) having a relatively high contact resistance.

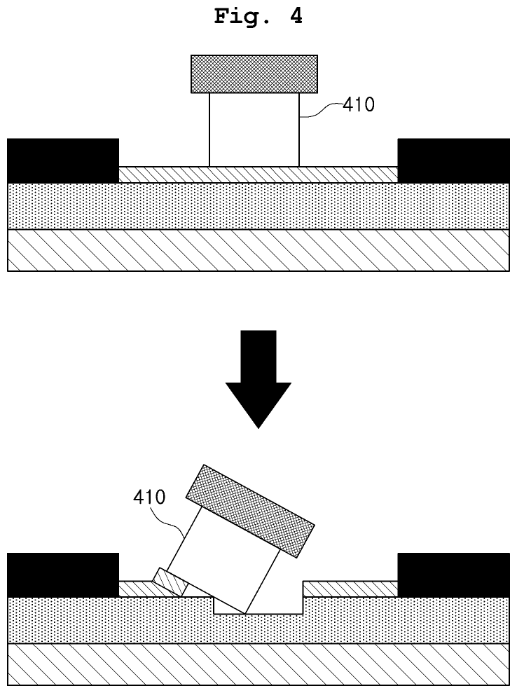

Therefore, as shown in FIG. 4, after the tip 410 of the probe card PC comes into contact with the pad of the wafer W, the probe card PC is additionally pressed to cause the tip 410 to slip. When the tip 410 slips, the oxide film (Al2O3) is peeled off and the tip 410 comes into contact with aluminum (Al). That is, sliding of the tip 410 of the probe card PC by a certain distance may lower the contact resistance, lower the voltage for testing, and lower the defect rate. When moisture level is too low in a high temperature environment, the resistance (slip resistance) to the tip of the probe card PC from sliding increases, and when there is certain amount of moisture, the slip resistance decreases. Thus, it may be said that maintaining a small amount of humidity (e.g., 3%) in the chamber 310 is advantageous in improving the inspection performance (test voltage and defect rate) of the wafer W.

Therefore, the present disclosure provides a method of supplying a predetermined amount of dry air to the chamber 310 even when testing in a high temperature environment, but at a level lower than the supply amount of dry air supplied in a low temperature environment in order to increase the inspection efficiency of the wafer W while reducing the amount of dry air used. The amount of dry air supplied in a high temperature environment may vary according to embodiments, and the scope of the present disclosure is not limited to specific values. For example, when the supply amount of the dry air supplied in the low temperature environment is 100 LPM (liter per minute), the supply amount of the dry air supplied in the high temperature environment may be 20 LPM. The supply flow rate of dry air may be variably adjusted according to the area of the chamber 310 and process conditions

Hereinafter, a wafer inspection apparatus and a wafer inspection method of the present disclosure for variably supplying dry air according to a test temperature will be described. In this document, the flow rate refers to the capacity through which a gas flows per unit time.

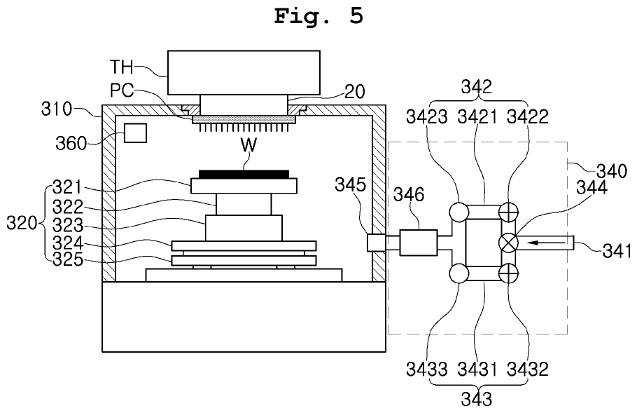

FIG. 5 shows a wafer inspection apparatus to which a dry air supply unit 340 is applied according to the embodiment of the present disclosure. The dry air supply unit 340 according to the embodiment of the present disclosure may include: an inlet 341 through which dry air is introduced; a first supply line 342 connected to the inlet 341 and configured for dry air to flow at a first flow rate (e.g., 100 LPM); a second supply line 343 connected to the inlet 341 and configured for dry air to flow at a second flow rate (e.g., 20 LPM) lower than the first flow rate; a switch valve 344 for guiding the dry air introduced through the inlet 341 to one of the first supply line 342 or the second supply line 343; and an outlet 345 connected to the first supply line 342 and the second supply line 343 for discharging dry air to the chamber 310. Also, a flow meter 346 may be provided at the outlet 345 to measure the flow rate of dry air discharged to the chamber 310.

Dry air is introduced through an inlet 341 from a tank or pipe that supplies dry air from the outside of the probe station 1, and after passing through one of the first supply line 342 or the second supply line 343, the dry air is discharged into the chamber 310 through the outlet 345. The switch valve 344 regulates the flow path by using a manual switch or an electrical signal to open one of the port connected to the first supply line 342 and the port connected to the second supply line 343 and close the other port.

According to the embodiment of the present disclosure, the first supply line 342 may include a first conduit 3421 through which the dry air can flow, a first speed controller 3422 for controlling the dry air to flow at the first flow rate in the first conduit 3421, and a first check valve 3423 for guiding the dry air to flow in a direction of the outlet 345 and blocking the dry air from flowing in an opposite direction of the outlet 345.

In addition, the second supply line 343 may include a second conduit 3431 through which the dry air can flow, a second speed controller 3432 for controlling the dry air to flow at the second flow rate in the second conduit 3431, and a second check valve 3433 for guiding the dry air to flow in a direction of the outlet 345 and blocking the dry air from flowing in an opposite direction of the outlet 345.

Dry air introduced through the inlet 341 passes through either the first conduit 3421 or the second conduit 3431 through the switch valve 344. Here, the flow rate of dry air is controlled by the first speed controller 3422 or the second speed controller 3432. The first speed controller 3422 and the second speed controller 3432 may be implemented by a valve whose opening area is adjusted according to a manual operation or an electrical signal. The first speed controller 3422 is set to have a relatively large opening amount so that the dry air constantly flows at the first flow rate, and the second speed controller 3432 is set to have a relatively small opening amount so that the dry air constantly flows at the second flow rate lower than the first flow rate. The supply flow rate of the dry air may be controlled by adjusting the opening amount of the first speed controller 3422 and the second speed controller 3432.

According to the embodiment, the switch valve 344 is controlled by the flow control unit 350, and the flow control unit 350 may control the flow direction of the dry air by controlling the opening direction of the switch valve 344, and consequently may adjust the flow rate of the dry air.

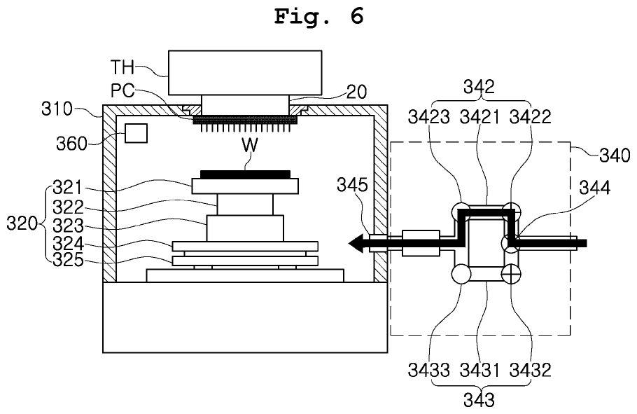

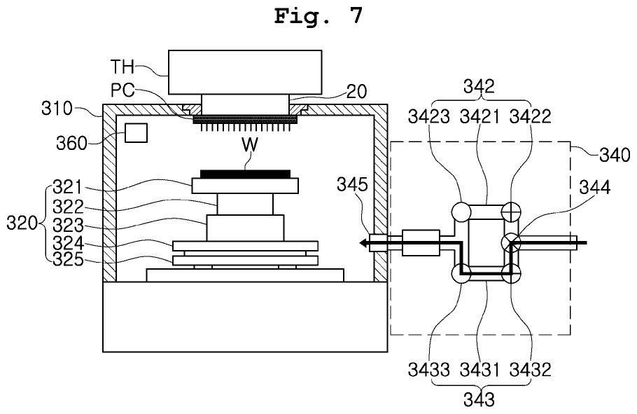

When the test temperature of the wafer W corresponds to a first temperature (e.g., −20° C.) corresponding to the low temperature, the flow control unit 350 may control the switch valve 344 so that dry air flows to the first supply line 342 as shown in FIG. 6. When the inspection temperature of the wafer W corresponds to a second temperature (e.g., 60° C.) corresponding to a high temperature, the flow control unit 350 may control the switch valve 344 so that dry air flows to the second supply line 343 as shown in FIG. 7.

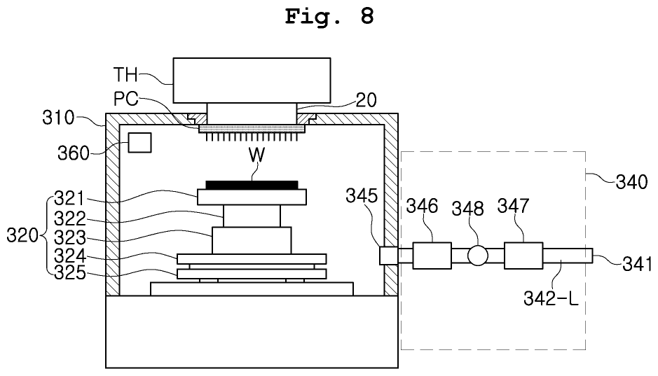

FIG. 8 shows a wafer inspection apparatus to which a dry air supply unit 340 is applied according to an embodiment of the present disclosure.

According to an embodiment of the present disclosure, the dry air supply unit 340 may include: an inlet 341 through which the dry air is introduced; a conduit 342-L connected to the inlet 341 and through which the dry air can flow; an electropneumatic regulator 347 provided in the conduit 342-L to variably control the flow rate at which the dry air flows; an outlet 345 connected to the conduit 342-L for discharging the dry air to the chamber 310; a flow meter 346 provided at the outlet 345 to measure the flow rate of the dry air discharged into the chamber 310; and a check valve 348 that blocks dry air from flowing in the opposite direction of the outlet 345.

According to the embodiment, the flow control unit 350 controls the electropneumatic regulator 347 to discharge the dry air at a first pressure corresponding to the first flow rate (e.g., 100 LPM) so that the dry air flows at the first flow rate when the test temperature corresponds to the first temperature (e.g., −20° C.). Also, the flow control unit 350 may control the electropneumatic regulator 347 to discharge the dry air at a second pressure corresponding to the second flow rate (e.g., 20 LPM) so that the dry air flows at the second flow rate when the test temperature corresponds to the second temperature (e.g., 60° C.) higher than the first temperature.

Meanwhile, according to an embodiment of the present disclosure, the supply flow rate of dry air may be controlled according to the humidity data measured by the hygrometer 360 provided in the chamber 310. That is, the flow control unit 350 may control the dry air supply unit 340 to increase the supply flow rate of the dry air when the humidity inside the chamber 310 measured by the hygrometer 360 is higher than the reference value, and may control the dry air supply unit 340 to decrease the supply flow rate of the dry air when the humidity inside the chamber 310 measured by the hygrometer 360 is lower than the reference value.

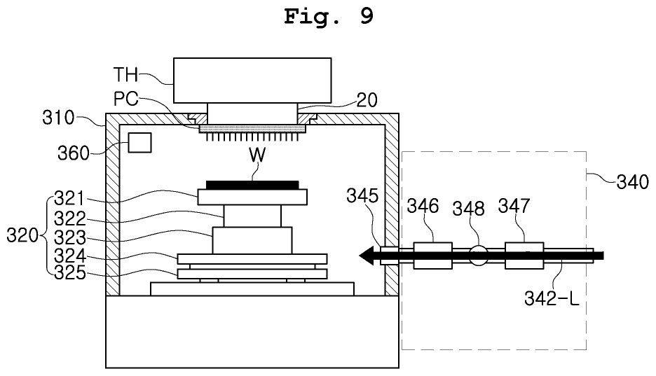

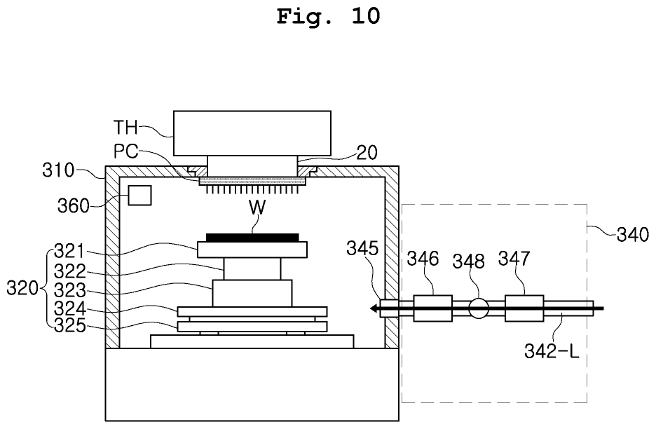

FIGS. 9 and 10 illustrate a process of supplying dry air from the dry air supply unit according to an embodiment of the present disclosure. When the test temperature of the wafer W corresponds to the first temperature (e.g., −20° C.) corresponding to the low temperature, the flow control unit 350 may control the electropneumatic regulator 347 for dry air to flow at a relatively large first flow rate as shown in FIG. 9. Also, when the test temperature of the wafer W corresponds to the first temperature (e.g., 60° C.) corresponding to the high temperature, the flow control unit 350 may control the electropneumatic regulator 347 for dry air to flow at a relatively small second flow rate as shown in FIG. 10.

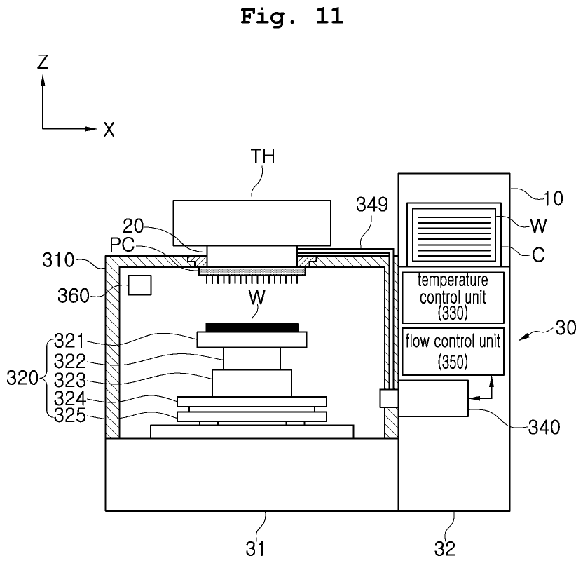

FIG. 11 shows a wafer inspection apparatus to which a dry air supply unit is applied according to an embodiment of the present disclosure. The condensation phenomenon described above may also occur on the probe card PC. Dry air is supplied to the side contacting the wafer W from the probe card PC to the chamber 310, but condensation may occur on the opposite side connected to the test head TH. Accordingly, in the embodiment of the present disclosure, dry air is supplied to the interface unit 20 to which the probe card PC and the test head TH are electrically connected.

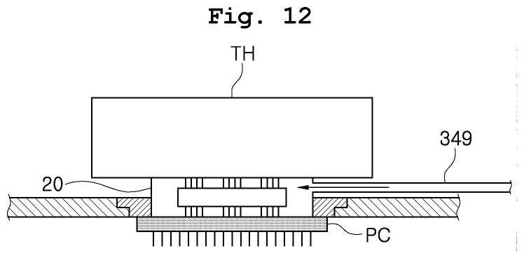

According to the embodiment, the dry air supply unit 340 may be configured to supply dry air to the interface unit 20. For example, as shown in FIGS. 11 and 12, a supply pipe 349 may extend from the dry air supply unit 340 to the interface unit 20, and dry air may be supplied to the interface unit 20 through the supply pipe 349.

As previously described, the flow rate of dry air supplied to the interface unit 20 may be determined based on the test temperature for the wafer W. That is, the flow control unit 350 may adjust the supply flow rate of the dry air supplied to the interface unit 20 based on the test temperature for the wafer W. For example, when the test temperature for the wafer W is low (e.g., −20° C.), the flow control unit 350 may supply dry air at a relatively high flow rate to the interface unit 20, and the test temperature for the wafer W is high (e.g., 60° C.), the flow control unit 350 may supply dry air at a relatively low flow rate to the interface unit 20 or may not supply dry air.

Meanwhile, an on-off valve may be provided in the supply pipe 34. Here, the on/off valve is opened and dry air is supplied to the interface unit 20 when the test temperature is low, and the on/off valve may be closed and dry air may not be supplied to the interface unit 20 when the test temperature of the wafer W is high.

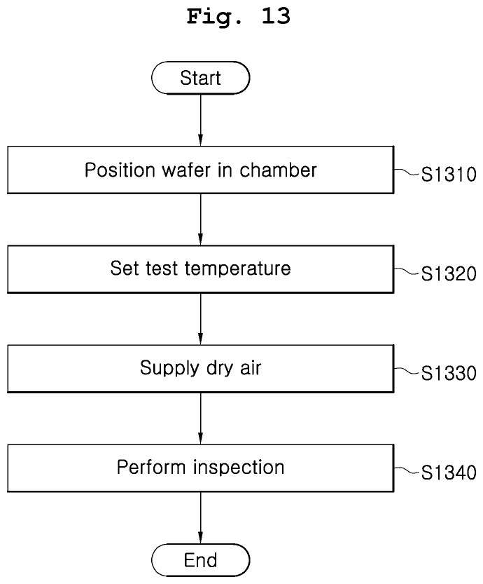

FIG. 13 is a flowchart illustrating a wafer inspection method according to the present disclosure. The wafer inspection method according to the present disclosure includes: placing S1310 a wafer W in a chamber 310; setting S1320 a test temperature of the wafer W; supplying S1330 dry air of a set flow rate to the chamber 310 based on the set test temperature; and performing S1340 an electrical test on the wafer W at the set test temperature.

In the step S1310, the wafer W is put into the loader unit 10 of the probe station 1 and transferred to the inside of the chamber 310 by the wafer transfer robot and then seated on the chuck 321. When the wafer W is seated on the chuck 321, the chuck 321 is moved by the first horizontal drive unit 324 and the second horizontal drive unit 325 so that the probe card PC and the wafer W are aligned.

In the step S1320, control of temperature for inspection of wafer W is performed. As previously described, the temperature inside the chamber 310 is adjusted to a low or high temperature by the temperature control unit 330 for testing in various temperature environments. The temperature control unit 330 may control the temperature of the wafer W by operating a heater or a cooler located inside the chuck 321.

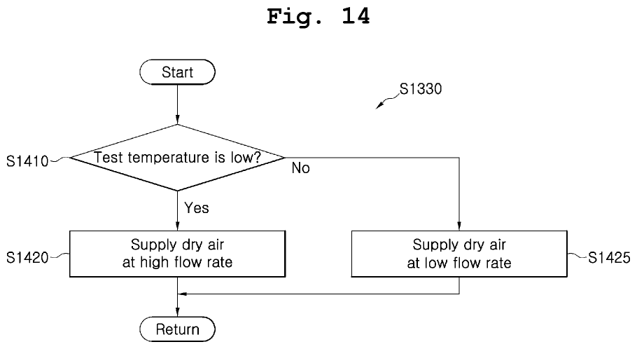

In the step S1330, dry air at a flow rate set based on the test temperature of the wafer W may be supplied to the chamber 310. FIG. 14 illustrates a process of supplying dry air to the chamber 310 according to an embodiment of the present disclosure. According to the embodiment of the present disclosure, the step of supplying S1330 dry air to the chamber 310 includes: checking the current test temperature S1410; supplying S1420 dry air to the chamber 310 at a relatively high first flow rate when the current test temperature corresponds to the first temperature (low temperature); and supplying S1425 dry air to the chamber 310 at a second flow rate smaller than the first flow rate when the test temperature corresponds to a second temperature (high temperature) higher than the first temperature.

The process of controlling and supplying the flow rate of dry air may be implemented by configuring a separate flow path as described with reference to FIGS. 5 to 7. Also, as described with reference to FIGS. 8 to 10, the process of controlling and supplying the flow rate of dry air may be implemented by configuring a single flow path but controlling the pressure of dry air discharged from the electropneumatic regulator 347.

Meanwhile, according to an embodiment of the present disclosure, the flow rate of dry air may be adjusted based on the humidity data measured inside the chamber 310. For example, the flow rate of the dry air supplied to the chamber 310 may be adjusted based on the humidity data measured by the hygrometer 360 provided in the chamber 310.

Finally, in the step S1340, an electrical test is performed on the wafer W. When the wafer W contacts the probe card PC, electrical signals are applied by the test head TH connected to the probe card PC, and the state of each semiconductor device may be inspected by analyzing the response of each semiconductor device on the wafer W to the input electrical signals.

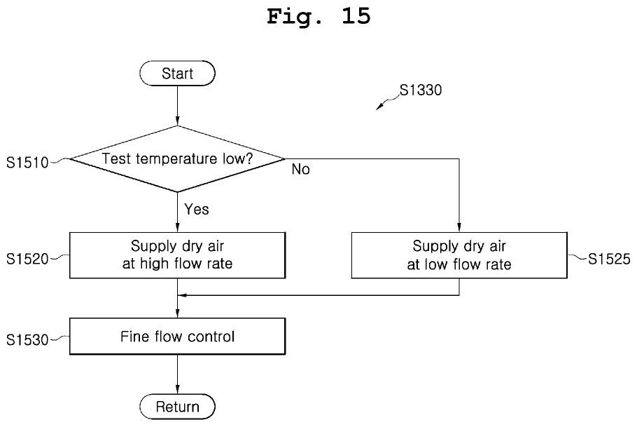

FIG. 15 shows an example of the step S1330 of supplying dry air according to an embodiment of the present disclosure. The step of supplying S1330 dry air includes: checking the current test temperature S1510; supplying S1520 dry air to the chamber 310 at a relatively high first flow rate when the current test temperature corresponds to the first temperature (low temperature); supplying S1525 dry air to the chamber 310 at a second flow rate smaller than the first flow rate when the test temperature corresponds to a second temperature (high temperature) higher than the first temperature; and adjusting 51530 the flow rate of dry air based on the humidity data inside the chamber 310.

The embodiments and the accompanying drawings in this specification only clearly show a part of the technical idea included in the present disclosure, and thus it will be apparent that all modifications and specific embodiments that can be easily inferred by those skilled in the art within the scope of the technical idea included in the specification and drawings of the present disclosure are included in the scope of the present disclosure.

Therefore, the spirit of the present disclosure should not be limited to the described embodiments, and not only the claims to be described later, but also all equivalents or equivalent modifications to the claims should be construed as being included in the scope of the spirit of the present disclosure.

What is claimed is:

1. A wafer inspection apparatus, comprising:
a chamber providing a space for an electrical test of a wafer;
a support unit positioned inside the chamber to support the wafer;
a temperature control unit for controlling a test temperature of the wafer;
a dry air supply unit for supplying dry air to the chamber; and
a flow control unit for controlling the dry air supply unit to adjust a flow rate of the dry air based on the test temperature.

2. The wafer inspection apparatus of claim 1, wherein the dry air supply unit includes:
an inlet through which the dry air is introduced;
a first supply line connected to the inlet and configured for the dry air to flow at a first flow rate;
a second supply line connected to the inlet and configured for the dry air to flow at a second flow rate lower than the first flow rate;
a switch valve for directing the dry air introduced through the inlet to one of the first supply line or the second supply line;
an outlet connected to each of the first supply line and the second supply line for discharging the dry air to the chamber; and
a flow meter provided at the outlet to measure the flow rate of the dry air discharged into the chamber.

3. The wafer inspection apparatus of claim 2, wherein the first supply line includes:
a first conduit through which the dry air flows;
a first speed controller for controlling the dry air to flow at the first flow rate in the first conduit; and
a first check valve for guiding the dry air to flow in a direction of the outlet and blocking the dry air from flowing in an opposite direction of the outlet.

4. The wafer inspection apparatus of claim 2, wherein the second supply line includes:
a second conduit through which the dry air flows;
a second speed controller for controlling the dry air to flow at the second flow rate in the second conduit; and
a second check valve for guiding the dry air to flow in a direction of the outlet and blocking the dry air from flowing in an opposite direction of the outlet.

5. The wafer inspection apparatus of claim 2, wherein the flow control unit controls the switch valve so that the dry air flows to the first supply line when the test temperature corresponds to a first temperature, and controls the switch valve so that the dry air flows to the second supply line when the test temperature corresponds to a second temperature higher than the first temperature.

6. The wafer inspection apparatus of claim 1, wherein the dry air supply unit includes:
an inlet through which the dry air is introduced;
a conduit connected to the inlet and through which the dry air flows;
an electropneumatic regulator provided in the conduit to variably control the flow rate at which the dry air flows;
an outlet connected to the conduit for discharging the dry air to the chamber; and
a flow meter provided at the outlet to measure the flow rate of the dry air discharged into the chamber.

7. The wafer inspection apparatus of claim 6, wherein the flow control unit controls the electropneumatic regulator to discharge the dry air at a first pressure corresponding to a first flow rate so that the dry air flows at the first flow rate when the test temperature corresponds to a first temperature, and controls the electropneumatic regulator to discharge the dry air at a second pressure corresponding to a second flow rate so that the dry air flows at the second flow rate when the test temperature corresponds to a second temperature higher than the first temperature.

8. The wafer inspection apparatus of claim 1, further comprising:
a hygrometer configured to measure humidity inside the chamber,
wherein the flow control unit adjusts a supply flow rate of the dry air based on humidity data measured by the hygrometer.

9. A wafer inspection method, comprising:
placing a wafer in a chamber;
setting a test temperature of the wafer;
supplying dry air of a set flow rate to the chamber based on the set test temperature; and
performing an electrical test on the wafer at the set test temperature.

10. The wafer inspection method of claim 9, wherein the supplying dry air to the chamber includes:
supplying the dry air to the chamber at a first flow rate when the test temperature corresponds to a first temperature; and
supplying the dry air to the chamber at a second flow rate smaller than the first flow rate when the test temperature corresponds to a second temperature higher than the first temperature.

11. A probe station, comprising:
a loader unit that loads a wafer and unloads an inspected wafer;
an inspection unit for contacting the wafer to a probe card for inspection of the wafer; and
an interface unit providing a space in which the probe card and a test head are electrically connected,
wherein the inspection unit includes:
a chamber providing a space for an electrical test of the wafer;
a temperature control unit for controlling a test temperature of the chamber;
a dry air supply unit for supplying dry air to the chamber; and
a flow control unit for adjusting a supply flow rate of the dry air based on the test temperature,
wherein the flow control unit supplies the dry air at a first flow rate when the test temperature is a first temperature, and supplies the dry air at a second flow rate lower than the first flow rate when the test temperature is a second temperature higher than the first temperature.

12. The probe station of claim 11, wherein the dry air supply unit includes:
an inlet through which the dry air is introduced;
a first supply line connected to the inlet and configured for the dry air to flow at the first flow rate;
a second supply line connected to the inlet and configured for the dry air to flow at the second flow rate lower than the first flow rate;
a switch valve for directing the dry air introduced through the inlet to one of the first supply line or the second supply line;
an outlet connected to each of the first supply line and the second supply line for discharging the dry air to the chamber; and
a flow meter provided at the outlet to measure a flow rate of the dry air discharged into the chamber.

13. The probe station of claim 12, wherein the first supply line includes:
a first conduit through which the dry air flows;
a first speed controller for controlling the dry air to flow at the first flow rate in the first conduit; and
a first check valve for guiding the dry air to flow in a direction of the outlet and blocking the dry air from flowing in an opposite direction of the outlet.

14. The probe station of claim 12, wherein the second supply line includes:
a second conduit through which the dry air flows;
a second speed controller for controlling the dry air to flow at the second flow rate in the second conduit; and
a second check valve for guiding the dry air to flow in a direction of the outlet and blocking the dry air from flowing in an opposite direction of the outlet.

15. The probe station of claim 12, wherein the flow control unit controls the switch valve so that the dry air flows to the first supply line when the test temperature corresponds to the first temperature, and controls the switch valve so that the dry air flows to the second supply line when the test temperature corresponds to the second temperature higher than the first temperature.

16. The probe station of claim 11, wherein the dry air supply unit includes:
an inlet through which the dry air is introduced;
a conduit connected to the inlet and through which the dry air flows;
an electropneumatic regulator provided in the conduit to variably control a flow rate at which the dry air flows;
an outlet connected to the conduit for discharging the dry air to the chamber; and
a flow meter provided at the outlet to measure a flow rate of the dry air discharged into the chamber.

17. The probe station of claim 16, wherein the flow control unit controls the electropneumatic regulator to discharge the dry air at a first pressure corresponding to the first flow rate so that the dry air flows at the first flow rate when the test temperature corresponds to the first temperature, and controls the electropneumatic regulator to discharge the dry air at a second pressure corresponding to the second flow rate so that the dry air flows at the second flow rate when the test temperature corresponds to the second temperature higher than the first temperature.

18. The probe station of claim 11, wherein the inspection unit further includes:
a hygrometer configured to measure humidity inside the chamber,
wherein the flow control unit adjusts the supply flow rate of the dry air based on humidity data measured by the hygrometer.

19. The probe station of claim 11, wherein the dry air supply unit is configured to supply the dry air to the interface unit.

20. The probe station of claim 19, wherein the flow control unit adjusts the supply flow rate of the dry air supplied to the interface unit based on the test temperature.
